(19) United States
(12) Patent Application Publication
(10) Pub. No.: US 2015/0324870 A1
(43) Pub. Date: Nov. 12, 2015

(54) Method of Remotely Determining the Condition of a Used Electronic Device

(71) Applicants: Tu Nguyen, Fremont, CA (US); Michael Smithwick, San Jose, CA (US); Kevin Ta, Fremont, CA (US)

(72) Inventors: Tu Nguyen, Fremont, CA (US); Michael Smithwick, San Jose, CA (US); Kevin Ta, Fremont, CA (US)

(21) Appl. No.: 14/477,794

(22) Filed: Sep. 4, 2014

Related U.S. Application Data
(60) Provisional application No. 62/024,462, filed on Jul. 14, 2014.
(60) Provisional application No. 61/992,160, filed on May 12, 2014.

(51) Int. Cl. G06Q 30/02; G01R 31/36; G01R 31/02

(52) U.S. Cl. CPC G06Q 30/0278; G01R 31/02; G01R 31/361

(57) ABSTRACT

A method of remotely performing a functional diagnostic and a cosmetic evaluation of a used electronic device, using an app installed on the device itself, and of using the evaluation data to determine a resale value for the device.

### CROSS-REFERENCE TO RELATED APPLICATIONS

The present application takes priority from Provisional Application No. 61/992,160, filed May 12, 2014, and Provisional Application No. 62/024,462, filed Jul. 14, 2014.

### STATEMENT REGARDING FEDERALLY SPONSORED RESEARCH AND DEVELOPMENT

Not applicable.

### BACKGROUND

1. Field of the Invention

The present invention relates generally to determining the condition of used electronic devices, and more particularly to a method for valuing a used electronic device remotely.

2. Description of the Related Art

It is often desirable to determine the condition of a used electronic device. For example, an electronic device company or a reseller buying back a used electronic device may wish to determine whether or not it is in good working order, what's broken, what's working, and so on. A repair shop specializing in repairing electronic devices may wish to perform a diagnostic test on a malfunctioning device to determine what works and what doesn't. An insurance company wishing to verify a claim made by a customer may wish to perform a diagnostic test on the device they insured.

Some of those diagnostic tests may need to be performed before a price quote is made. For example, a reseller may need to determine whether or not the device is in good working order before making an offer to the consumer. A repair shop may need to perform a diagnostic test before quoting a price for the repairs.

A consumer wishing to resell an old electronic device, or wishing to get their device repaired, would usually need to go to the resale location or to the repair shop for such diagnostic tests to be performed. Typically, the consumer does not know what price they'll get for their used device, or how much the repair will cost, until they arrive at the shop. This leads to nasty surprises, in the case of repair costs, and to disappointment, in the case of price offers. In some cases, the customer would not have gone to the shop at all had they known what the amount was going to be.

A need therefore exists for a method of verifying the condition of an electronic device remotely and providing a price quote for the electronic device or for repairing the electronic device.

### SUMMARY OF THE INVENTION

An object of the present invention is to perform a functional test on a used electronic device via an application installed on the device itself.

Another object of the present invention is to perform a cosmetic evaluation of a used electronic device via an application installed on the device itself.

Another object of the present invention is to determine a resale value for a used electronic device via an application installed on the device itself.

Another object of the present invention is to perform a diagnostic for a problem with a used electronic device via an application installed on the device itself.

For purposes of the present disclosure, a “used electronic device” may be a smartphone, mp3 player, tablet, laptop, gaming device, or any other device capable of running an application and transmitting data to a server.

In the preferred embodiment of the present invention, an application is installed on an electronic device. The application determines the identifying information for the electronic device, such as the device ID number, the manufacturer and model, user name, and so on. The application also performs a functional test on the electronic device. Such a functional test may include a battery test, a test of the cell phone function of the device, a test of the wi-fi transmission, a test of the touchscreen, a test of the buttons, and so on. The results of the functional test are then transmitted to an online server, which looks up pricing information for used electronic devices of the same type and in the same condition as the electronic device.

In the preferred embodiment of the present invention, the application also performs a cosmetic test on the electronic device. The object of the cosmetic test is to determine the cosmetic condition of the electronic device—i.e. to evaluate the number of scratches, cracks, scuff marks, and other cosmetic imperfections. The electronic device's own camera is preferably used to take photos of the electronic device in front of a mirror; the application preferably directs the user to hold the electronic device in the correct position and at the correct distance in front of the mirror for the photo or photos to be taken. If the electronic device has two or more cameras, the application can direct the user to turn the device in such a way that each camera can take a photo of the electronic device in the mirror. The application may also direct the user to hold a second mirror in such a way that at least one of the left side, right side, top side, or bottom side of the device are visible to at least one camera of the electronic device.

In an embodiment, the application may display a rectangular frame on the device screen for the purpose of alignment of the device image prior to taking a photo of the device. In another embodiment, the photo is taken automatically when the user positions the used electronic device correctly and at the proper orientation.

The photos are then analyzed to determine the cosmetic condition of the device. In the preferred embodiment, at least one or more visual parameters of the photo are changed to heighten the contrast level, luminence, or tonal range to make cosmetic imperfections more visible. The number, type, location, and size of cosmetic imperfections are then used to produce a cosmetic score for the device. The analysis may be performed on the device itself or on a server.

In an embodiment, information regarding the device is steganographically encoded in at least one of the photos taken during the cosmetic evaluation. The information may comprise the device ID, user name, device make and model, or some parameter of the photo itself (to prevent tampering). The information may also comprise the functional test results, cosmetic evaluation results, and pricing information. The information may be encrypted.

The cosmetic and functional test results are then conveyed to a server. Depending on what the user desires, the test results are then used to determine a resale value for the device, to determine a repair quote for the device, or to determine the value of an insurance payout for the device.

### LIST OF FIGURES

FIG. 1 shows the first part of a flowchart of the method of the preferred embodiment of the present invention.

FIG. 2 shows the second part of a flowchart of the method of the preferred embodiment of the present invention.

### DETAILED DESCRIPTION OF THE PREFERRED EMBODIMENT

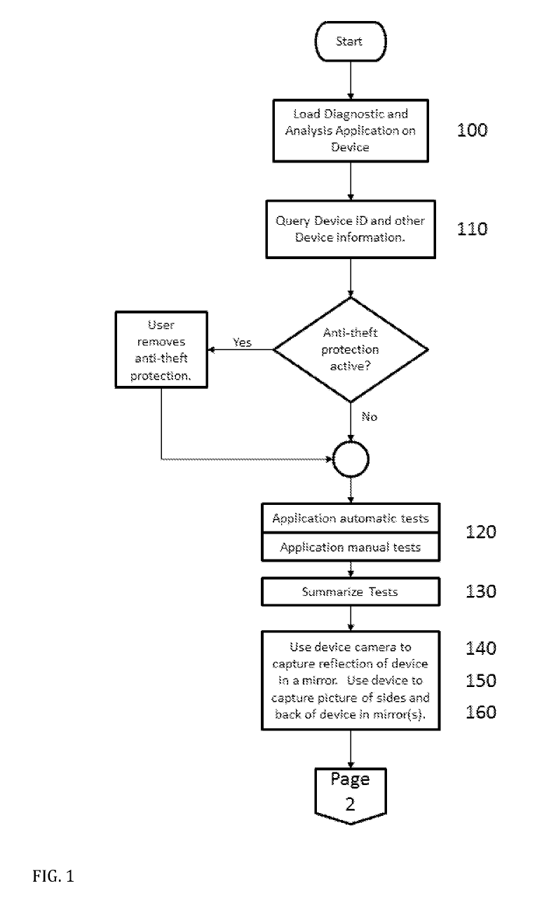

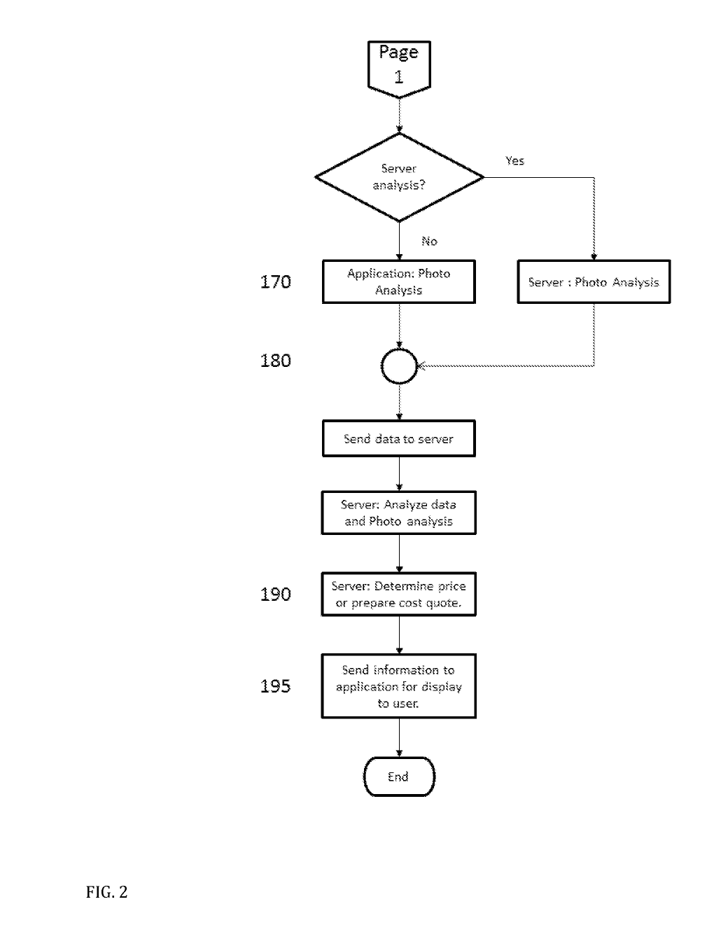

FIGS. 1 and 2 show a flowchart of the method of the preferred embodiment of the present invention. The user first installs an application on the used electronic device 100. Then, the application queries the device 110 to determine its device ID number, manufacturer and model, operating system type, user name, and so on. In an embodiment, the application may also query the device to determine if security software such as Find My iPhone is turned on, and instruct the user to turn it off.

The application then performs a functional test 120 on the used electronic device. In the preferred embodiment, the functions tested comprise the battery, telephone, wi-fi, buttons, touchscreen, camera or cameras, screen, Bluetooth, speaker, microphone, earphones, and so on. Some of the tests are conducted automatically, whereas some other tests may require the user to interact with the used electronic device (i.e. by pushing the buttons or touching the touchscreen). In an embodiment, the user is able to specify ahead of time which functions should be included in the functional test.

After the functional test is performed, the test results are summarized 130. The application then performs a cosmetic test on the device.

The first step of the cosmetic test is instructing the user to hold the used electronic device in front of a mirror and use one camera of the used electronic device to take a photo of the device 140. The application preferably directs the user to hold the used electronic device in the correct position and at the correct distance from the mirror for the photo to be taken. In the preferred embodiment, a rectangular frame is shown on the screen of the device for the user to align the photo. The photo is then taken automatically when the device is at the correct distance and orientation with respect to the mirror. Preferably, the correct distance is the closest focal distance of the device camera, so the largest clear photo may be taken.

In an embodiment, the next step of the cosmetic test is instructing the user to hold the used electronic device in front of a mirror and use another camera of the used electronic device to take a photo of the device 150. The user may also be instructed to hold a second mirror up to the device in such a way as to take a photo of the right side, left side, top side, or bottom side of the device 160. Any number of photos may be taken. The photos are preferably taken automatically when the device is positioned correctly, but they may also be taken manually by the user. In the preferred embodiment, the photos show all six sides of the used electronic device.

The photos are then analyzed 170 to determine a cosmetic score for the used electronic device. Preferably, the photos are processed to heighten the visibility of any cosmetic imperfections, then analyzed to determine the number, type, and length of each cosmetic imperfection. The types of cosmetic imperfections are preferably cracks, scratches, scuffs, and other miscellaneous imperfections. In the preferred embodiment, in each category, the imperfections are sorted into length ranges—for example, 2-4 mm, 4-6 mm, 6-8 mm, and so on. The number of imperfections in each range is multiplied by the average length, and the numbers are added together to get a score for each category of imperfection. Then, the scores are weighted based on the type of imperfection and location—cracks are weighted heavier than scuffs, and scratches on the screen are weighted heavier than scratches on the case, for example. Finally, the weighted scores are added to get a cosmetic score. In an embodiment, the cosmetic score is also used to determine a cosmetic category such as “Like New”, “Used”, “Heavily Used”, and so on.

The cosmetic test results and the functional test results are then transmitted to a server 180, along with information identifying the device. Depending on what the user wants—a repair quote, a resale value, an insurance payout value—the server then searches the Web, or a proprietary database, for resale value of similar devices, repair quotes for devices with similar problems, or insurance payout values for similar devices in similar conditions 190. The information may come from any website that specializes in resale of used electronic devices, a proprietary insurance company database, a repair shop database, or anywhere else.

After finding a value, or several values, for devices of the same type in similar conditions, the server then sends the data to the application and the application displays this data for the user 195. The user is then aware of the potential resale value for their device without having to go anywhere, or of the repair quote for their device before going to the repair shop. In an embodiment, the user can agree to a resale price for the device before going to the resale facility, and the price will be honored by the resale facility. In an embodiment the user can agree to a repair price for the device before going to the repair facility and the price will be honored by the repair facility.

In an embodiment, the application communicates with the server at regular intervals to determine the resale value of the used electronic device and sends a push notification to the user to alert them of the resale value of their device, or of any changes to the resale value of their device.

While exemplary embodiments have been described above, those skilled in the art will readily realize that numerous changes, modifications, and substitutions may be made without departing from the spirit and scope of this invention, which is limited only by the appended claims.

1. A method of determining the value of a used electronic device, comprising:
installing an application on the used electronic device;
using the application to determine identifying information for the used electronic device, said identifying information comprising at least one of the device ID number, manufacturer, and model;
using the application to perform a functional test on the used electronic device;
transmitting data regarding the condition of the used electronic device to an online server;
using the online server to look up pricing information for used electronic devices in the same condition as the used electronic device;
using the application to display the pricing information.

2. The method of claim 1, further comprising:
prior to the transmitting step, using the application to perform a cosmetic evaluation on the used electronic device.

3. The method of claim 1, where using the application to perform a functional test on the used electronic device comprises at least one of the following group of steps:
testing the battery;
testing the touchscreen;
testing the buttons;
testing the telephony functions;
testing the wi-fi connection;
testing the Bluetooth connection;
testing each camera;
testing the speaker;
testing the SMS function;
testing the MMS function;
testing the video recording and playback function;
testing the microphone.

4. The method of claim 2, where using the application to perform a cosmetic evaluation of the used electronic device comprises:
instructing a user to hold the used electronic device in front of a mirror;
using at least one camera of the used electronic device to take a photo of the used electronic device;
analyzing the photo to determine the cosmetic condition of the used electronic device.

5. The method of claim 4, further comprising:
instructing a user to hold the used electronic device in front of a mirror in such a way that a second camera of the used electronic device is facing the mirror;
using the second camera to take a second photo of the used electronic device;
analyzing the second photo to determine the cosmetic condition of the used electronic device.

6. The method of claim 4, further comprising:
instructing a user to hold a second mirror and the used electronic device in front of a mirror in such a way that at least one of the left side, right side, top side, or bottom side of the device is visible in the mirror;
using a camera to take a third photo of the used electronic device, said third photo showing at least one of the left side, right side, top side, or bottom side of the used electronic device;
analyzing the third photo to determine the cosmetic condition of the used electronic device.

7. The method of claim 4, where the instructing step includes informing the user of the proper distance between the used electronic device and the mirror.

8. The method of claim 4, where the instructing step includes displaying a rectangular frame on the device screen for alignment of the photo.

9. The method of claim 7, where the photo is taken automatically when the user holds the used electronic device at the proper distance from and in the proper orientation to the mirror.

10. The method of claim 4, where information regarding the device is steganographically encoded in at least one photo, said information comprising at least one of the device ID, date, time, manufacturer, model, user name, functional test results, cosmetic evaluation result, pricing information.

11. The method of claim 9, where the information is encrypted.
